(19) United States
(12) Patent Application Publication
(10) Pub. No.: US 2023/0060594 A1
(43) Pub. Date: Mar. 2, 2023

(54) CASTELLATION, HATCHING, AND OTHER SURFACE PATTERNS IN DIELECTRIC SURFACES FOR HYBRID BONDING WITH INCREASED SURFACE AREA, BOND STRENGTH, AND ALIGNMENT

(71) Applicant: Micron Technology, Inc., Boise, ID (US)

(72) Inventor: Kyle K. Kirby, Eagle, ID (US)

(21) Appl. No.: 17/858,001

(22) Filed: Jul. 5, 2022

Related U.S. Application Data
(60) Provisional application No. 63/238,071, filed on Aug. 27, 2021.

(51) Int. Cl. H01L 23/00; H01L 25/065

(52) U.S. Cl. CPC H01L 24/08; H01L 25/0657; H01L 24/05; H01L 24/03; H01L 24/80; H01L 24/09; H01L 2225/06524; H01L 2225/06527; H01L 2224/80143; H01L 2224/80895; H01L 2224/80896; H01L 2224/0361; H01L 2224/05687; H01L 2224/05693; H01L 2224/09055; H01L 2224/0903; H01L 2224/09133; H01L 2224/0801; H01L 2224/08055; H01L 2224/08059; H01L 2224/08145

(57) ABSTRACT

A semiconductor device includes a semiconductor substrate having a first major surface and a second major surface opposite the first major surface, a first layer of dielectric material over the first major surface, and a second layer of dielectric material over the second major surface. The first layer includes a plurality of recesses, and the second layer includes a plurality of protrusions. Each of the plurality of recesses are defined by a shape, and each of the plurality of protrusions are vertically aligned with a corresponding one of the plurality of recesses and are defined by the shape of the corresponding one of the plurality of recesses.

### CROSS-REFERENCE TO RELATED APPLICATION(S)

The present application claims priority to U.S. Provisional Patent Application No. 63/238,071, filed Aug. 27, 2021, the disclosure of which is incorporated herein by reference in its entirety.

### TECHNICAL FIELD

The present technology generally relates to semiconductor devices having surface patterns in dielectric surfaces, and more particularly having surface patterns for increasing surface area, bond strength, and alignment of hybrid and fusion bonding of semiconductor die stacks.

### BACKGROUND

Semiconductor device manufacturers often seek to make smaller, faster, and/or more powerful devices with a higher density of components for computers, cells phones, pagers, personal digital assistants, and many other products. Die manufacturers have come under increasing pressure to reduce the volume occupied by the dies and yet increase the capacity of the resulting encapsulated assemblies. To meet these demands, die manufacturers often stack multiple dies on top of each other to increase the capacity or performance of the device within the limited surface area on the circuit board or other element to which the dies are mounted. The stacked semiconductor devices, e.g., three-dimensional integrated circuits (3DICs), generally enjoy a reduced footprint compared with conventional arrangement.

Fusion and hybrid bonding are bonding procedures for forming 3DICs. In fusion bonding, a dielectric bond is formed between the dielectric layers of two facing semiconductor dies. Hybrid bonding further includes metal-metal bonds formed between conductive structures of the dies. Hybrid bonding shows great promise for forming assemblies with reduced height and better thermal performance; accordingly, improved approaches to hybrid bonding are greatly desired.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1A is cross-sectional view of a semiconductor device having protrusions and recesses in accordance with an embodiment of the present technology, FIG. 1B is an enlarged cross-sectional view of the semiconductor device of FIG. 1A, and FIG. 1C is a bottom plan view of the semiconductor device of FIG. 1A.

FIGS. 2A and 2B are cross-sectional views of another semiconductor device including a plurality of protrusions and recesses in accordance with an embodiment of the present technology.

FIGS. 2C and 2D are enlarged cross-sectional views of a semiconductor device having protrusions and recesses in accordance with embodiments of the present technology.

FIG. 3 is a cross-sectional view of a semiconductor die having a plurality of recesses and protrusions in accordance with an embodiment of the present technology.

FIG. 4A is cross-sectional view of a semiconductor device having a plurality of recesses and protrusions in accordance with an embodiment of the present technology, and FIG. 4B is a bottom plan view of the semiconductor device of FIG. 4A.

FIG. 5 is a cross-sectional view of a semiconductor die having a plurality of recesses and protrusions in accordance with an embodiment of the present technology.

FIG. 6A is a cross-sectional view of a semiconductor device before assembly in accordance with an embodiment of the present technology, and FIG. 6B is a cross-sectional view of the semiconductor device of FIG. 6A after assembly.

FIG. 7 is a flowchart of a method of forming a semiconductor device in accordance with an embodiment of the present technology.

FIG. 8 is a schematic view of a system that includes a semiconductor assembly configured in accordance with embodiments of the present technology.

### DETAILED DESCRIPTION

Specific details of several embodiments of semiconductor devices having surface patterns in dielectric surfaces to improve fusion and hybrid bonding are disclosed. In some embodiments, for example, a semiconductor device includes a semiconductor substrate having a first major surface and a second major surface opposite the first major surface. The semiconductor device can also include a first layer of dielectric material over the first major surface. The first layer can include a plurality of recesses, and each of the plurality of recesses can be defined by a shape. The semiconductor device can further include a second layer of dielectric material over the second major surface. The second layer can include a plurality of protrusions. Each of the plurality of protrusions can be vertically aligned with a corresponding one of the plurality of recesses and be defined by the shape of the corresponding one of the plurality of recesses. The present technology can increase surface area, bond strength, and alignment during fusion and hybrid bonding for semiconductor devices.

A person skilled in the relevant art will recognize that, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

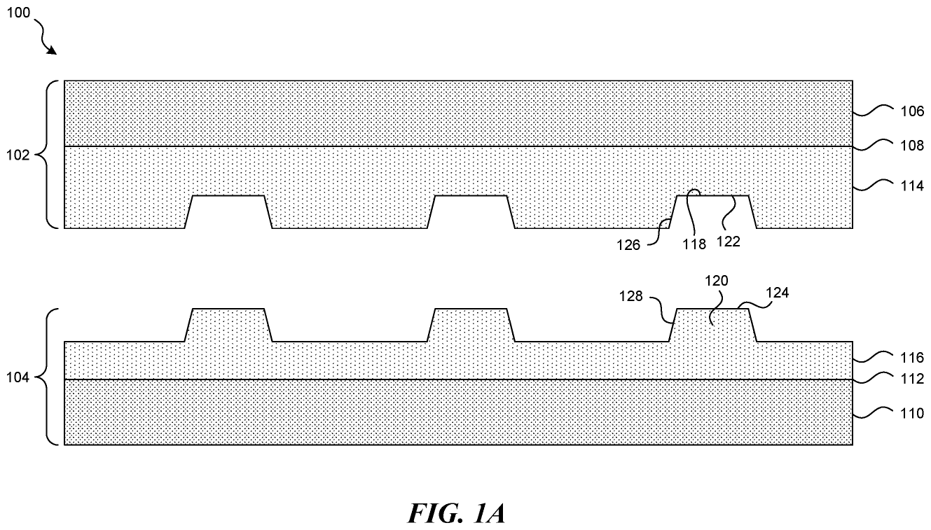

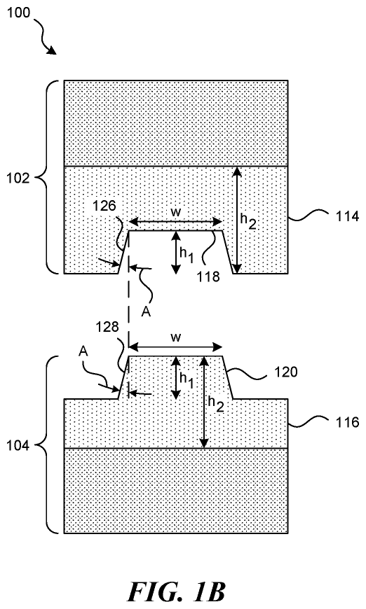

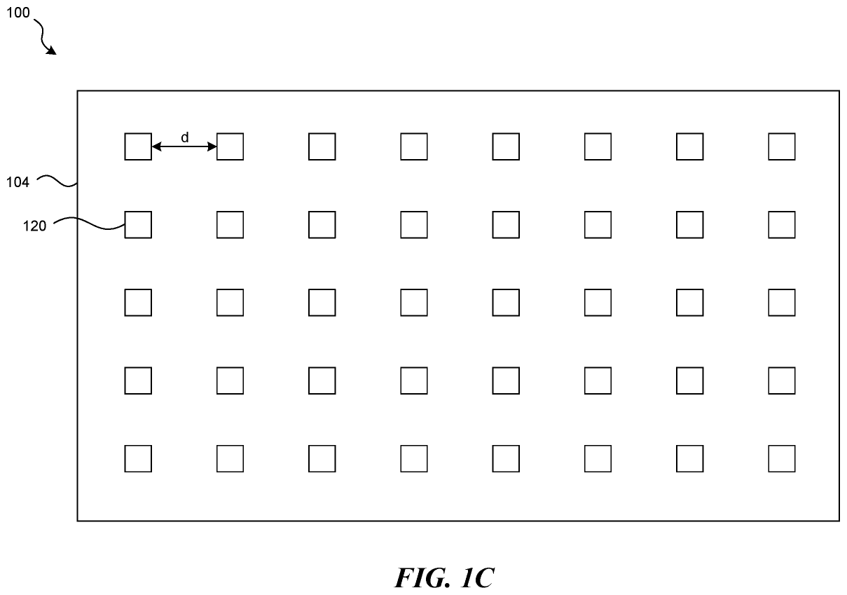

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 1A-7. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

FIG. 1A is cross-sectional view of a semiconductor device (“device 100”) including a plurality of recesses and protrusions in accordance with an embodiment of the present technology. The device 100 includes two semiconductor dies 102 and 104 (“dies 102 and 104”). The die 102 includes a substrate 106 having a first major surface 108, and the die 104 includes a substrate 110 having a second major surface 112 opposite the first major surface 108. The die 102 includes a first dielectric layer 114 over the first major surface 108, and the die 104 includes a second dielectric layer 116 over the second major surface 112. The first dielectric layer 114 can comprise a same dielectric material as the second dielectric layer 116. The material of the first and second dielectric layers 114 and 116 can include tetraethyl orthosilicate, silicon carbon nitride, silicon dioxide, or a combination thereof.

Referring to FIGS. 1A and 1B together, the first dielectric layer 114 includes a plurality of recesses 118, and the second dielectric layer 116 includes a plurality of protrusions 120. Each of the plurality of protrusions 120 can be vertically aligned with a corresponding one of the plurality of recesses 118. Each of the plurality of recesses 118 and protrusions 120 is defined by a longitudinal cross-sectional shape. The longitudinal cross-sectional shape can be trapezoidal, rectangular, square, rectilinear, or any other suitable shape. Each of the plurality of recesses 118 includes a flat bottom surface 122, and each of the plurality of protrusions 120 includes a flat top surface 124. The plurality of recesses 118 can be formed by etching away material from the first dielectric layer 114. The plurality of protrusions 120 can be formed by etching away material from the second dielectric layer 116.

Referring to FIG. 1B, each of the plurality of recesses 118 and protrusions 120 have sidewalls 126 and 128, respectively, which have a same angle A, height h₁, and width w. The angle A can be within a range from 0 to almost 90 degrees. In some embodiments, the angle A is within a range from 0 to 45 degrees. The height h₁ can be no more than 2, 4, or 6 microns. The width w can be no more 2, 4, or 6 microns. In some embodiments, the height h₁ and the width w are the same. In other embodiments, the height h₁ is less than the width w. In other embodiments, the height h₁ is greater than the width w. The first and second dielectric layers 114 and 116 includes a height h₂. The height h₂ is at least the height h₁. For example, the height h₂ can be 2, 4, 6, 8, 10 microns, or any suitable height greater than height h₁. In the illustrated embodiment, the height h₂ of the first and second dielectric layers 114 and 116 is greater than the height h₁ of the plurality of recesses 118 and protrusions 120. In other embodiments, the height h₂ is approximately equal to the height h₁. Although FIG. 1B illustrates the first and second dielectric layers 114 and 116 having the same height h₂, the first dielectric layer 114 can have a height different than the second dielectric layer 116.

Each of the plurality of recesses 118 and protrusions 120 can have any suitable number of sidewalls and dimensions. In some embodiments, each of the plurality of recesses 118 and protrusions 120 can have three or more sidewalls. For example, each of the plurality of recesses 118 and protrusions 120 can have three sidewalls, four sidewalls (as illustrated in FIG. 1C), five sidewalls, six sidewalls, or any suitable number of sidewalls. Each sidewall can have the same or different dimensions. For example, each sidewall can have the same or different heights and/or angles.

Referring to FIG. 1C, in some embodiments, the plurality of protrusions 120 of the die 104 comprises perpendicular rows and columns of protrusions. In this embodiment, the plurality of recesses 118 of the die 102 comprises perpendicular rows and columns of recesses. Each of the plurality of protrusions 120 are spaced apart by a distance d. The distance d can be any suitable distance. In some embodiments, the distance d can be at least the width w of each of the plurality of recesses 118 and protrusions and 120. In other embodiments, the distance d can be no more than the width w. In yet other embodiments, the distance d can be approximately the width w. For example, the distance d can be 2, 4, 6, 8, 10, 15, or 20 microns, or any suitable distance. Each of the plurality of recesses 118 and protrusions 120 is defined by a transverse cross-sectional shape. The transverse cross-sectional shape can be rectangular, square, rectilinear, or any other suitable shape. Although FIG. 1C illustrates each of the plurality of protrusions 120 being equally spaced apart by the distance d, each or a portion of the plurality of protrusions 120 may be spaced apart by different distances. Furthermore, although FIG. 1C illustrates the device 100 having forty protrusions and accordingly forty recesses, the device 100 can include fewer or more protrusions and recesses. For example, the device 100 can include any number of protrusions and recesses in a range from one to forty or more than forty.

The plurality of recesses 118 and protrusions 120 can have any suitable pattern of arrangement on the dies 102 and 104, respectively. In the illustrated embodiment of FIG. 1C, the plurality of recesses 118 and protrusions 120 are arranged in aligned perpendicular rows and columns of recesses and protrusions. In other embodiments, the plurality of recesses 118 and protrusions 120 can have staggered perpendicular rows and columns of protrusions and recesses. Moreover, in yet other embodiments, the plurality of recesses 118 and protrusions 120 need not be arranged in perpendicular columns and rows, but can be arranged in other patterns readily apparent to those of skill in the art (e.g., in hexagonal arrays, along radiating lines of symmetric, in non-symmetric arrangements, etc.). In still other embodiments, the plurality of recesses 118 and protrusions 120 may all have similar dimensions, or may be configured with differing dimensions (e.g., to accommodate other features on the die). For example, some corresponding pairs of recesses 118 and protrusions 120 can be configured with one dimension much larger than the other, to provide an elongated pair extending substantially the dimension of the dies 102 and 104.

The plurality of recesses 118 and protrusions 120 can provide an increased surface area of the dies 102 and 104, respectively, compared to without the plurality of recesses and protrusions. As one of skill in the art will readily appreciate, the surface area of the dies 102 and 104 depends on the height h₁, sidewall angle A, distance d, and number of recesses and protrusions. In some embodiments, the plurality of recesses 118 and protrusions 120 can provide an increase in surface area of each of the dies 102 and 104, respectively, by 10% to 300%. For example, the increase in surface area of each of the dies 102 and 104 can be 10%, 30%, 60%, 120%, 240%, 300%, or any suitable percentage.

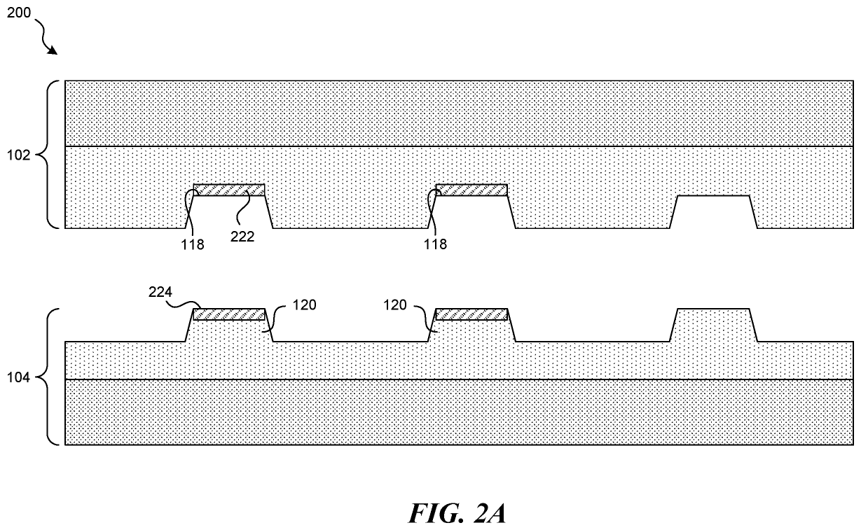

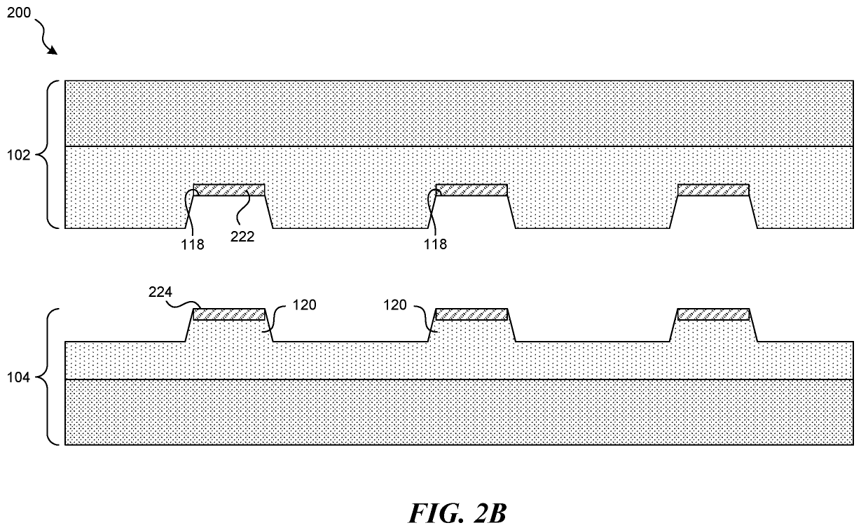

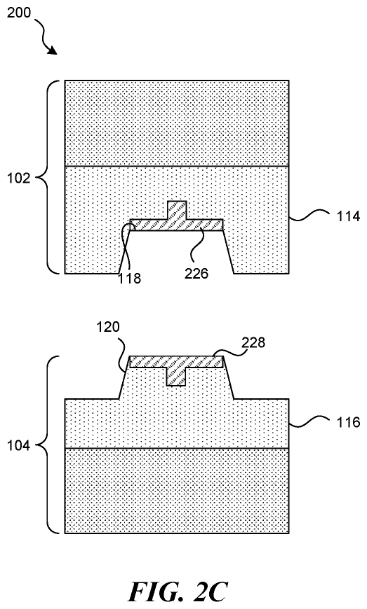

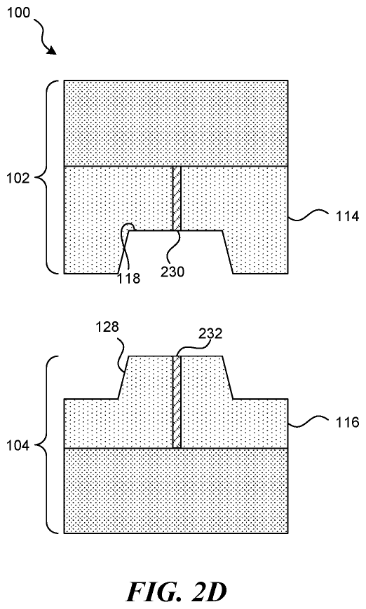

FIGS. 2A and 2B are cross-sectional views of a semiconductor device 200 (“device 200”) including a plurality of recesses and protrusions in accordance with an embodiment of the present technology. The device 200 is generally similar to the device 100, except that the device 200 further includes dies 102 and 104 having first and second conductive contacts 222 and 224, respectively. At least one of the plurality of recesses 118 includes a first conductive contact 222 disposed therein, and at least the corresponding one of the plurality of protrusions 120 includes a second conductive contact 224 disposed thereon. Referring to FIG. 2A, in some embodiments, one or more of the plurality of recesses 118 and protrusions 120 include the first and second conductive contacts 222 and 224, respectively. Referring to FIG. 2B, in some embodiments, each of the plurality of recesses 118 and protrusions 120 include the first and second conductive contacts 222 and 224, respectively. The first and second conductive contacts 222 and 224 can include conductive material, such as but not limited to copper, silver, gold, zinc oxide, aluminum, and tin. As one with skill in the art will appreciate, the first and second conductive contacts 222 and 224 are connected to active or passive circuity (not illustrated) on the dies 102 and 104, respectively. For example, the first and second conductive contacts 222 and 224 can be connected by traces, vias, and other conductive components (not illustrated) to the dies 102 and 104, respectively. In some embodiments, the first and second conductive contacts 222 and 224 are approximately the same size or have approximately the same dimensions. In some embodiments, the first and second conductive contacts 222 and 224 have different dimensions. For example, the first conductive contact 222 can have a larger cross-sectional width than the second conductive contact 224, or vice versa.

FIG. 2C is an enlarged cross-sectional view of the semiconductor device 200 of FIG. 2A, except the dies 102 and 104 include a first dual damascene pad 226 and a second dual damascene pad 228, respectively. The first and second dual damascene pads 226 and 228 can be formed by patterning the dielectric layers 114 and 116, followed by depositing a conductive material and planarization.

FIG. 2D is another enlarged cross-sectional view of the semiconductor device 200 of FIG. 2A, except the dies 102 and 104 include a first via 230 and a second via 232, respectively. Besides the dual damascene pads 226 and 228 of FIG. 2C and the vias 230 and 232 of FIG. 2D, other structures can be embedded in the recesses 118 and protrusions 120 to electrically couple the dies 102 and 104 or connect components of the dies 102 and 104, such as the conductive contacts 222 and 224 shown in FIGS. 2A-B.

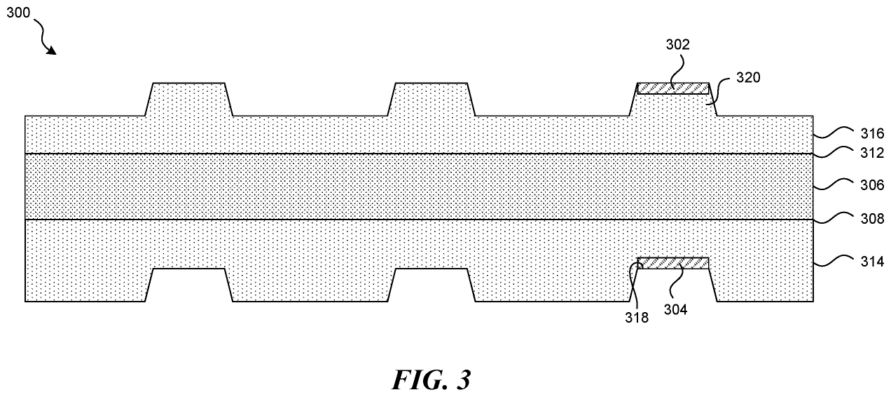

FIG. 3 is a cross-sectional view of a semiconductor die 300 (“die 300”) having a plurality of recesses and protrusions in accordance with an embodiment of the present technology. The die 300 includes a substrate 306 having a first major surface 308 and a second major surface 312 opposite the first major surface 308. The die 300 includes a first dielectric layer 314 over the first major surface 308 and a second dielectric layer 316 over the second major surface 312. The first dielectric layer 314 includes a plurality of recesses 318, and the second dielectric layer 316 includes a plurality of protrusions 320. Each of the plurality of protrusions 320 can be vertically aligned with a corresponding one of the plurality of recesses 318.

Referring to FIG. 3, the first and second dielectric layers 314 and 316 can generally be similar to or the same as the first and second dielectric layers 114 and 116 of device 100, respectively. The plurality of recesses 318 and protrusions 320 can generally be the same or share features similar to the plurality of recesses 118 and protrusions 120 of device 100, respectively, as described in reference to FIGS. 1A-1C, or the plurality of recesses and protrusions 218 and 220 of device 200, respectively, as described in reference to FIGS. 2A and 2B. In the illustrated embodiment, for example, at least one of the plurality of recesses 318 includes a first conductive contact 302 disposed therein, and at least the corresponding one of the plurality of protrusions 320 includes a second conductive contact 304 disposed thereon. Although FIG. 3 illustrates one of the plurality of recesses 318 and protrusions 320 having the first and second conductive contacts 302 and 304, respectively, in other embodiments, each or none of the plurality of recesses 318 and protrusions 320 can include conductive contacts. As one with skill in the art will appreciate, the first and second conductive contacts 302 and 304 are connected to active or passive circuity in the die 300 and to each other by through-substrate vias (not illustrated).

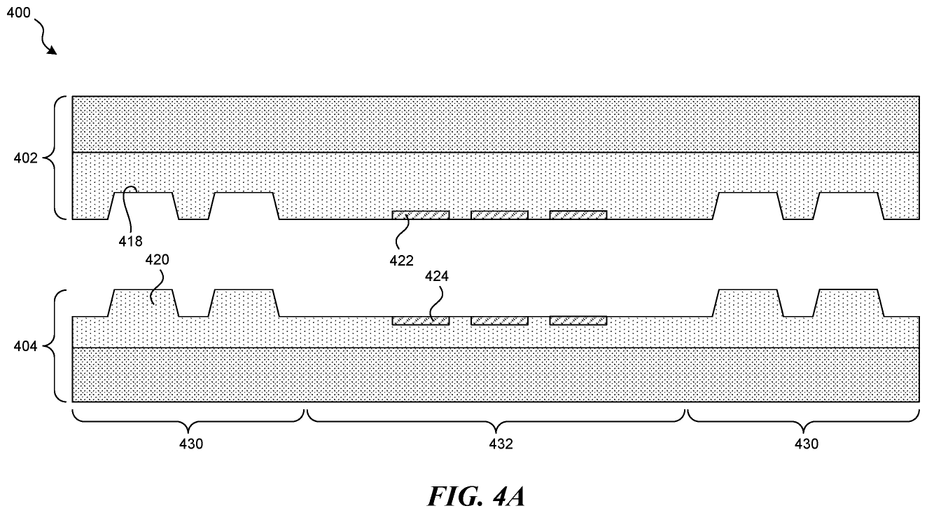

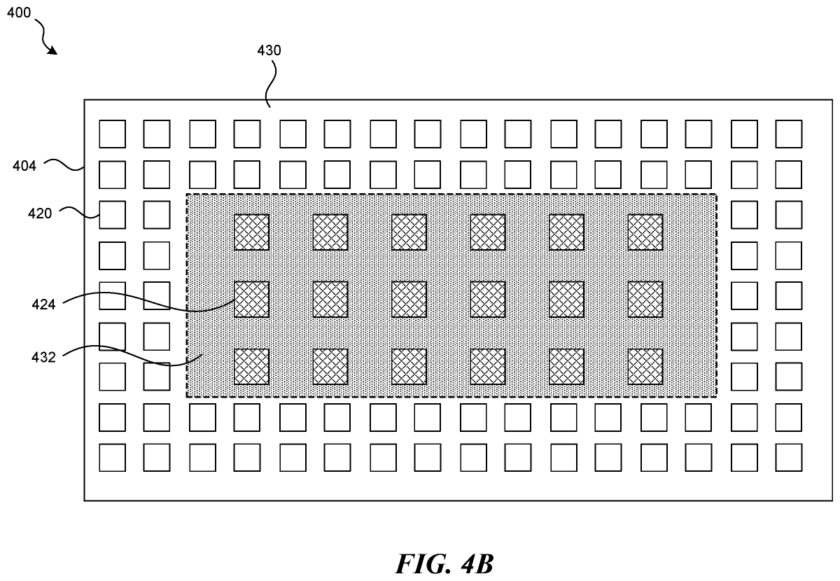

FIG. 4A is cross-sectional view of a semiconductor device 400 (“device 400”) having a plurality of recesses and protrusions in accordance with an embodiment of the present technology. The device 400 is generally similar to the device 100 as described in reference to FIGS. 1A-1C, except that the device 400 includes semiconductor dies 402 and 404 (“dies 402 and 404”) having a plurality of recesses and protrusions 418 and 420 located at a peripheral portion 430 surrounding a central portion 432 of the device 400. The device 400 further includes first and second conductive contacts 422 and 424 located at the central portion 432. Referring to FIG. 4B, in some embodiments, the plurality of protrusions 420 comprises perpendicular rows and columns of protrusions, and the second conductive contacts 424 are located at the central portion 432. In this embodiment, the plurality of recesses 418 of die 402 comprises perpendicular rows and columns of recesses. Although FIG. 4A illustrates the first and second conductive contacts 422 and 424 located only at the central portion 432, the first and second conductive contacts 422 and 424 may be located at only the plurality of recesses and protrusions 418 and 420, at both the central portion 432 and the plurality of recesses and protrusions 418 and 420, or at the central portion 432 and a portion of the plurality of recesses and protrusions 418 and 420. Although FIG. 4B illustrates the device 400 having 84 protrusions and accordingly 84 recesses, the device 100 can include fewer or more protrusions and recesses. For example, the device 100 can include any number of protrusions and recesses in a range from one to 84 or more than 84.

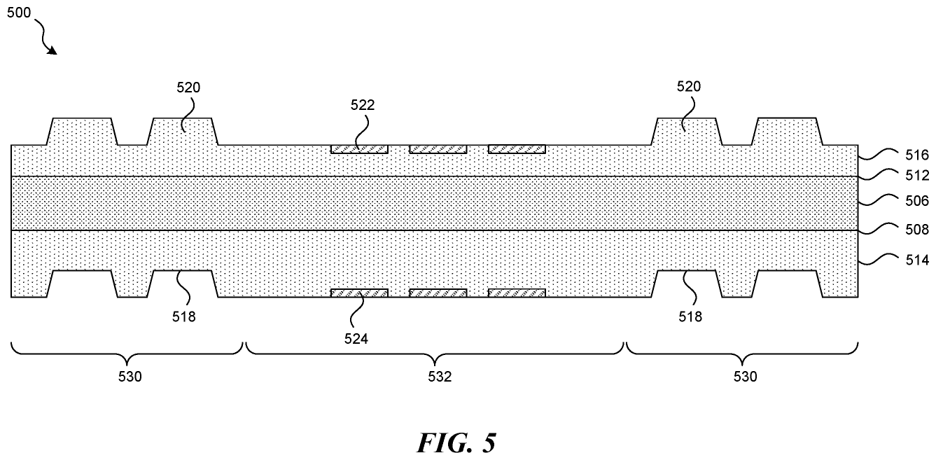

FIG. 5 is a cross-sectional view of a semiconductor die 500 (“die 500”) having a plurality of recesses and protrusions in accordance with an embodiment of the present technology. The die 500 includes a substrate 506 having a first major surface 508 and a second major surface 512 opposite the first major surface 508. The die 500 includes a first dielectric layer 514 over the first major surface 508 and a second dielectric layer 516 over the second major surface 512. The first dielectric layer 514 includes a plurality of recesses 518, and the second dielectric layer 516 includes a plurality of protrusions 520. The die 500 is generally similar to die 300 as described in reference to FIG. 3, with the exception that the plurality of recesses and protrusions 518 and 520 are located at a peripheral portion 530 surrounding a central portion 532 of the die 500. In the illustrated embodiment, the die 500 further includes first and second conductive contacts 522 and 524 disposed on the first and second dielectric layers 514 and 516, respectively, at the central portion 532. In some embodiments, one or more of the plurality of recesses 518 can include the first conductive contact 522 disposed therein, and at least the corresponding one of the plurality of protrusions 520 can include the second conductive contact 524 disposed thereon. In other embodiments, the first and second conductive contacts 522 and 524 can be disposed on only one or more of the plurality of recesses and protrusions 518 and 520.

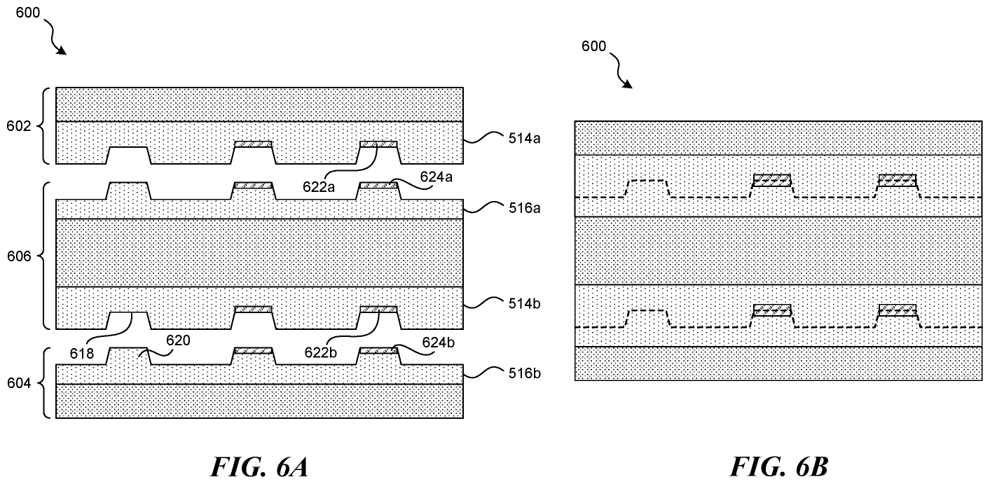

FIG. 6A is a cross-sectional view of a semiconductor device 600 (“device 600”) before assembly, and FIG. 6B is a cross-sectional view of the device 600 after assembly. The device 600 includes semiconductor dies 602, 604, and 606 (“dies 602, 604, and 606”). The dies 602 and 604 can be generally similar to or the same as the dies 102 and 104, respectively, as described in reference to FIGS. 1A-2B or the dies 402 and 404, respectively, as described in reference to FIGS. 4A-4B. The die 606 can be generally similar to or the same as the die 300 as described in reference to FIG. 3 or the die 500 as described in reference to FIG. 5. The die 602 is stacked over die 606, which is stacked over die 604. Each of the plurality of protrusions 620 are vertically aligned with a corresponding one of the plurality of recesses 618. A dielectric layer 514a of die 602 bonds with a dielectric layer 516a of die 606, and a dielectric layer 514b of die 606 bonds with a dielectric layer 516b of die 604 (bond shown in dashed lines in FIG. 6B). In some embodiments, upon assembly, first conductive contacts 622a and 622b are electrically coupled to second conductive contacts 624a and 622b, respectively. Although FIGS. 6A and 6B illustrate the device 600 having three semiconductor dies 602, 604, and 606, the device 600 can include fewer or more semiconductor dies.

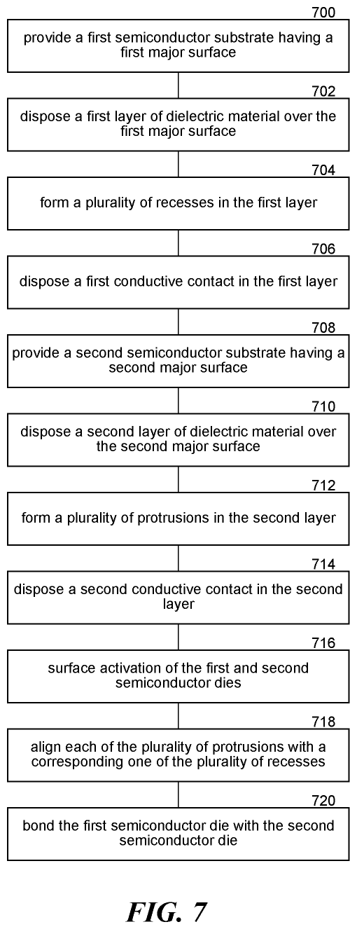

FIG. 7 is a flowchart of a method of forming a semiconductor device in accordance with an embodiment of the present technology. Steps 700 and 702 forms a first semiconductor die. At step 700 of the method, a first semiconductor substrate having a first major surface is provided. At step 702, a first layer of dielectric material is disposed over the first major surface of the first semiconductor substrate. At step 704, the first layer of dielectric material is etched to form a plurality of recesses in the first layer. Each of the plurality of recesses is defined by a shape. At step 706, a first conductive contact is disposed in the first layer of dielectric material. In some embodiments, the first conductive contact is disposed during step 704 while the first layer is etched. In other embodiments, the first conductive contact is disposed after step 704 (e.g., after the first layer is etched).

Steps 708 and 710 forms a second semiconductor die. At step 708 of the method, a second semiconductor substrate having a second major surface is provided. At step 710, a second layer of dielectric material is disposed over the second major surface of the second semiconductor substrate. At step 712, the second layer of dielectric material is etched to form a plurality of protrusions in the second layer. Each of the plurality of protrusions is defined by the shape of the corresponding one of the plurality of recesses. At step 714, a second conductive contact is disposed in the second layer of dielectric material. In some embodiments, the second conductive contact is disposed during step 712 while the second layer is etched. In other embodiments, the second conductive contact is disposed after step 712 (e.g., after the second layer is etched).

At step 716, the first and second semiconductor dies are surface activated (e.g., via plasma activation). At step 718, each of the plurality of protrusions of the first semiconductor die are aligned with a corresponding one of the plurality of recesses. At step 720, the first semiconductor die is bonded with the second semiconductor die, including electrically coupling the first conductive contact with the second conductive contact.

Although FIGS. 1A-6B illustrates each dielectric layer of the semiconductor devices and/or dies having either a plurality of recesses or a plurality of protrusions, in some embodiments, each dielectric layer can include both recesses and protrusions. For example, the semiconductor device can include the first dielectric layer of the first semiconductor die having a plurality of recesses and protrusions and the second dielectric layer of the second semiconductor die having a plurality of corresponding protrusions and recesses.

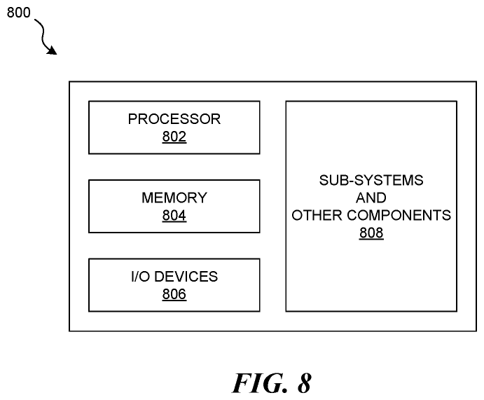

Any one of the semiconductor devices and/or dies having the features described above with reference to FIGS. 1A-7 can be incorporated into any of a myriad of larger and/or more complex systems, a representative example of which is system 800 shown schematically in FIG. 8. The system 800 can include a processor 802, a memory 804 (e.g., SRAM, DRAM, flash, and/or other memory devices), input/output devices 806, and/or other subsystems or components 808. The semiconductor dies and/or packages described above with reference to FIGS. 1A-7 can be included in any of the elements shown in FIG. 8. The resulting system 800 can be configured to perform any of a wide variety of suitable computing, processing, storage, sensing, imaging, and/or other functions. Accordingly, representative examples of the system 800 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 800 include lights, cameras, vehicles, etc. With regard to these and other examples, the system 800 can be housed in a single unit or distributed over multiple interconnected units (e.g., through a communication network). The components of the system 800 can accordingly include local and/or remote memory storage devices and any of a wide variety of suitable computer-readable media.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

What is claimed:

1. A semiconductor device, comprising:
a semiconductor substrate having a first major surface and a second major surface opposite the first major surface;
a first layer of dielectric material over the first major surface, the first layer including a plurality of recesses, each of the plurality of recesses being defined by a shape; and
a second layer of dielectric material over the second major surface, the second layer including a plurality of protrusions, each of the plurality of protrusions being vertically aligned with a corresponding one of the plurality of recesses and being defined by the shape of the corresponding one of the plurality of recesses.

2. The semiconductor device of claim 1, wherein at least one of the plurality of recesses includes a first conductive contact disposed therein, and at least the corresponding one of the plurality of protrusions includes a second conductive contact disposed thereon.

3. The semiconductor device of claim 1, wherein at least one of the plurality of recesses includes a first dual damascene pad, and at least the corresponding one of the plurality of protrusions includes a second dual damascene pad.

4. The semiconductor device of claim 1, wherein at least one of the plurality of recesses includes a first conductive via, and at least the corresponding one of the plurality of protrusions includes a second conductive via.

5. The semiconductor device of claim 1, wherein each of the plurality of recesses includes a flat bottom surface.

6. The semiconductor device of claim 1, wherein each the plurality of protrusions includes a flat top surface.

7. The semiconductor device of claim 1, wherein the plurality of protrusions comprises perpendicular rows and columns of protrusions.

8. The semiconductor device of claim 1, wherein the dielectric material includes tetraethyl orthosilicate, silicon carbon nitride, silicon dioxide, or a combination thereof.

9. A semiconductor device, comprising:
a first semiconductor die including:
a first semiconductor substrate having a first major surface, and
a first layer of dielectric material over the first major surface, the first layer including a plurality of recesses, each of the plurality of recesses being defined by a shape; and
a second semiconductor die including:
a second semiconductor substrate having a second major surface opposite the first major surface, and
a second layer of dielectric material over the second major surface, the second layer including a plurality of protrusions, each of the plurality of protrusions being vertically aligned with a corresponding one of the plurality of recesses and being defined by the shape of the corresponding one of the plurality of recesses.

10. The semiconductor device of claim 9, wherein at least one of the plurality of recesses includes a first conductive contact disposed therein, and at least the corresponding one of the plurality of protrusions includes a second conductive contact disposed thereon.

11. The semiconductor device of claim 9, wherein at least one of the plurality of recesses includes a first dual damascene pad, and at least the corresponding one of the plurality of protrusions includes a second dual damascene pad.

12. The semiconductor device of claim 9, wherein each one of the plurality of recesses includes a first surface and first sidewalls, and each one of the plurality of protrusions includes a second surface and second sidewalls having the same dimensions as the first surface and first sidewalls, respectively.

13. The semiconductor device of claim 12, wherein the first sidewalls are configured at an angle and the second sidewalls are configured at a same angle of the first sidewalls.

14. The semiconductor device of claim 13, wherein the angle is greater than 0 degrees and less than 90 degrees.

15. The semiconductor device of claim 9, wherein the first layer of dielectric material comprises a same material as the second layer of material.

16. A method of forming a semiconductor device, the method comprising:
forming a first semiconductor die including:
providing a first semiconductor substrate having a first major surface, and
providing a first layer of dielectric material over the first major surface;
forming a plurality of recesses in the first layer, each of the plurality of recesses being defined by a shape;
forming a second semiconductor die including:
providing a second semiconductor substrate having a second major surface, and
providing a second layer of dielectric material over the second major surface;
forming a plurality of protrusions in the second layer, each of the plurality of protrusions being defined by the shape of a corresponding one of the plurality of recesses; and
aligning each of the plurality of protrusions with the corresponding one of the plurality of recesses.

17. The method of claim 16, further comprising:
providing a first conductive contact in the first layer of dielectric material and a second conductive contact in the second layer of dielectric material.

18. The method of claim 17, further comprising:
electrically coupling the first conductive contact with the second conductive contact.

19. The method of claim 16, wherein forming the recesses comprises etching away material from the first dielectric layer.

20. The method of claim 16, wherein forming the protrusions comprises etching away material from the second dielectric material.
